(19) United States
(12) Patent Application Publication
(10) Pub. No.: US 2010/0039868 A1
(43) Pub. Date: Feb. 18, 2010

(54) Low voltage, low power single poly EEPROM

(76) Inventors: Allan T. Mitchell, Heath, TX (US); Harvey J. Stiegler, Plano, TX (US)

Correspondence Address: TEXAS INSTRUMENTS INCORPORATED, P O BOX 655474, M/S 3999, DALLAS, TX, 75265, US

(21) Appl. No.: 12/462,076

(22) Filed: Jul. 28, 2009

Related U.S. Application Data
(60) Provisional application No. 61/088,200, filed on Aug. 12, 2008.

(51) Int. Cl. G11C 16/04; H01L 27/115

(52) U.S. Cl. 365/185.28; 257/300; 365/185.29; 257/E27.103; 365/185.27

(57) ABSTRACT

An Electrically Erasable Programmable Read Only Memory (EEPROM) memory cell (FIGS. 1-2) is disclosed. The memory cell includes a sense transistor (152) having a source (110), a drain (108), and a control gate layer (156). The memory cell includes a first lightly doped region (160) having a first conductivity type and a second lightly doped region (162) having the first conductivity type. A first dielectric region is formed between the control gate layer and the first lightly doped region. A second dielectric region is formed between the control gate layer and the second lightly doped region.

### CLAIM TO PRIORITY OF NONPROVISIONAL APPLICATION

This application claims the benefit under 35 U.S.C. §119(e) of Provisional Appl. No. 61/088,200, filed Aug. 12, 2008, which is incorporated herein by reference in its entirety.

### BACKGROUND OF THE INVENTION

Embodiments of the present invention relate to an Electrically Erasable Programmable Read Only Memory (EEPROM) cell having a single polycrystalline silicon gate.

Contemporary semiconductor integrated circuits typically perform much more complex functions than previous designs. Mixed mode circuits performing combined analog, digital, and memory functions are common for many applications. At the same time these mixed mode circuits must keep the manufacturing process as simple as possible to reduce cost and improve the process yield. A single polycrystalline silicon EEPROM cell that may be manufactured together with analog and digital circuits on a single integrated circuit is one such example. The EEPROM cell permits nonvolatile memory to be formed in mixed mode circuits for many applications. Chi et al. (U.S. Pat. No. 5,940,324) and Chen et al. (U.S. Pat. No. 6,930,002) both developed single polycrystalline silicon EEPROM cells that are programmed by band-to-band tunneling. The present inventors have developed an improved single polycrystalline silicon EEPROM cell that offers several advantages over single polycrystalline silicon memory cells of the prior art as will become apparent in the following discussion.

### BRIEF SUMMARY OF THE INVENTION

In a preferred embodiment of the present invention, an Electrically Erasable Programmable Read Only Memory (EEPROM) cell is disclosed. The memory cell includes a sense transistor having a source, a drain, and a control gate layer. A first dielectric region is formed between a first part of the control gate layer and a first lightly doped region of a substrate having a first conductivity type. A second dielectric region is formed between a second part of the control gate layer and a second lightly doped region of a substrate having the first conductivity type. The memory cell preferably employs Fowler-Nordheim tunneling for both program and erase operations.

### BRIEF DESCRIPTION OF THE SEVERAL VIEWS OF THE DRAWING

FIG. 1 is a top view of a single polycrystalline silicon gate EEPROM cell of the present invention;

FIG. 2 is a cross sectional view of the EEPROM cell of FIG. 1 at the plane A-A′;

FIG. 3 is a cross sectional view of the EEPROM cell of FIG. 1 at the plane B-B′;

FIG. 4A is a cross sectional view as in FIG. 2 showing programming a logical zero (program) in the EEPROM cell;

FIG. 4B is a schematic diagram showing the programming of FIG. 4A;

FIG. 5A is a cross sectional view as in FIG. 2 showing programming a logical one (erase) in the EEPROM cell; and

FIG. 5B is a schematic diagram showing the programming of FIG. 5A.

### DETAILED DESCRIPTION OF THE INVENTION

Preferred embodiments of the present invention provide significant advantages in single polycrystalline silicon EEPROM memory cells as will become evident from the following detailed description. In the following discussion, P and N are used to indicate semiconductor conductivity type. A “+” or “−” sign after the conductivity type indicates a relatively high or low doping concentration, respectively, of the semiconductor region. Furthermore, the same reference numerals are used in the drawing figures to indicate common circuit elements.

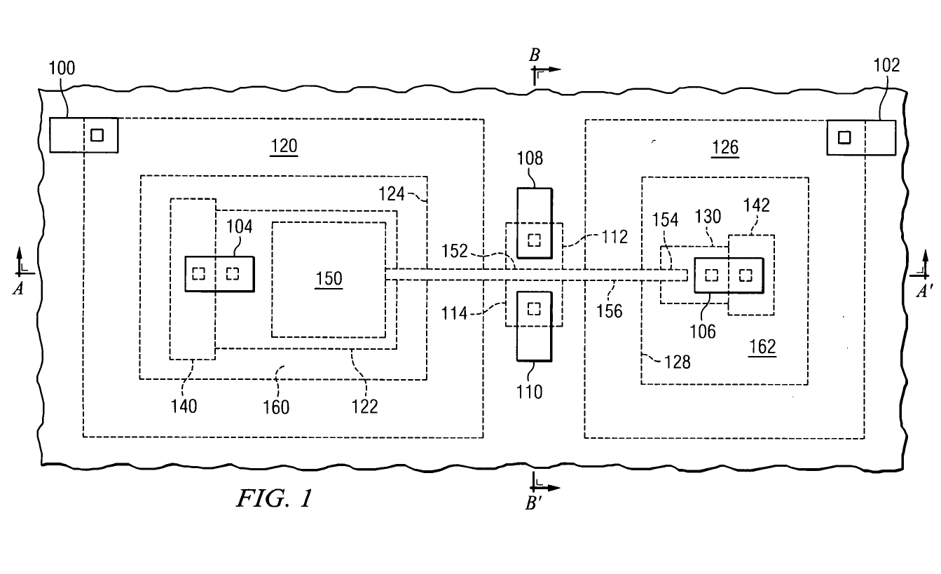

Referring to FIG. 1, there is a top view of a single polycrystalline silicon gate (Poly) EEPROM memory cell of the present invention. The cell includes N− isolation regions 120 and 126. These N− isolation regions serve to electrically isolate P− well regions 160 and 162, respectively, from a P type substrate. In operation, they are preferably biased to a positive supply voltage at terminals 100 and 102. A control gate terminal 104 contacts P+ region 140 as well as N+ region 122, both of which are formed within P− well region 160. A tunnel gate terminal 106 contacts P+ region 142 as well as N+ region 130, both of which are formed within P− well region 162. A single polycrystalline silicon gate layer 156 overlies a part of both P− well regions and is self aligned with N+ regions 122 and 130. An N-channel sense transistor is formed between the P− well regions 160 and 162. The sense transistor includes drain terminal 108, source terminal 110, and control gate 152. The sense transistor operates to indicate the data state of the polycrystalline silicon gate layer 156 as will be explained in detail.

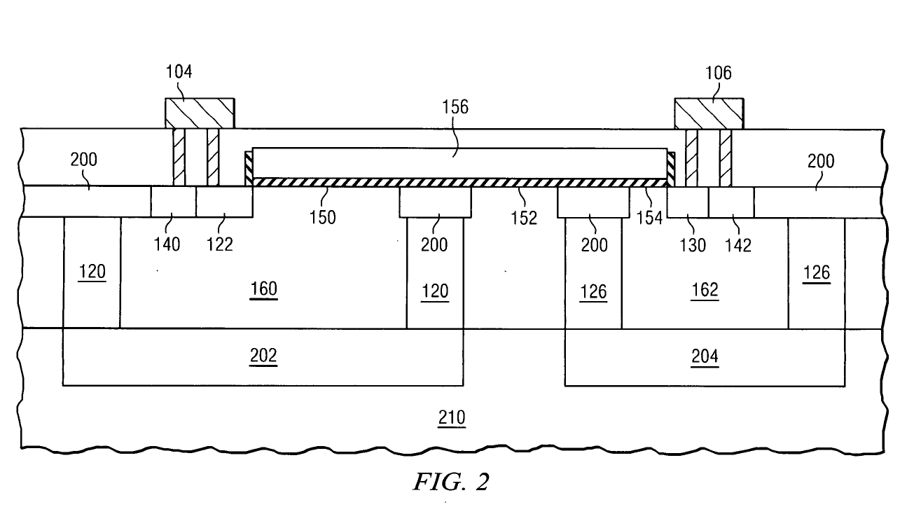

The polycrystalline silicon gate layer 156 is often referred to as a floating gate, since it is only capacitively coupled and not directly connected to other elements of the memory cell. The polycrystalline silicon gate forms one terminal of a control gate capacitor 150 as well as one terminal of a tunnel gate capacitor 154. Referring now to FIG. 2, there is a cross sectional view of the EEPROM cell of FIG. 1 at the plane A-A′. An N+ buried layer 202 together with N− isolation region 120 electrically isolates P− well region 160 from P substrate 210. Likewise, another N+ buried layer 204 together with N− isolation region 126 electrically isolates P− well region 162 from P substrate 210. Shallow trench isolation regions 200 isolate active regions such as control gate capacitor 150, sense transistor 152, and tunnel gate capacitor 154. An upper plate of the control gate capacitor is formed by a first part of polycrystalline silicon gate layer 156. A lower plate of the control gate capacitor is formed adjacent the upper plate by P− well region 160. The upper and lower plates are separated by a dielectric region to form the control gate capacitor 150. In a similar manner, an upper plate of the tunnel gate capacitor 154 is formed by a second part of polycrystalline silicon gate layer 156. A lower plate of the tunnel gate capacitor 154 is formed adjacent the upper plate by P− well region 162. The upper and lower plates are separated by a dielectric region to form the tunnel gate capacitor 154.

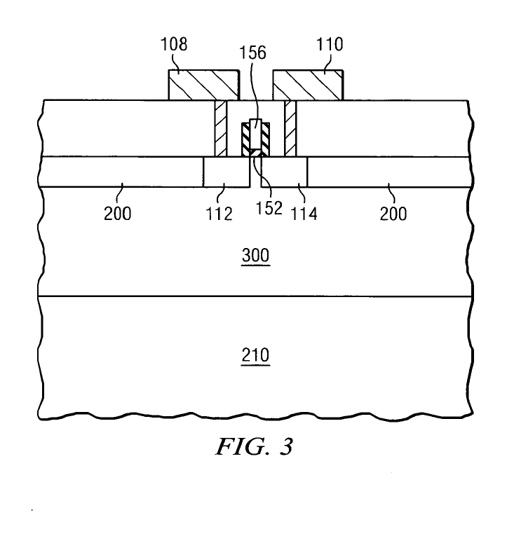

Referring now to FIG. 3, there is a cross sectional view of the EEPROM cell of FIG. 1 at the plane B-B′ showing the N-channel sense transistor. The sense transistor is formed in P− well region 300 over P substrate 210. The P− well region 300 is electrically isolated from P− well regions 160 and 162 as previously discussed. The sense transistor includes an N+ drain region 112 connected to terminal 108 and an N+ source region 114 connected to terminal 110. The drain 112 and source 114 regions are separated by a channel region controlled by polycrystalline silicon gate layer 156. Shallow trench isolation regions 200 isolate the drain 112 and source 114 regions from other active areas.

When a logical “1” is stored in the EEPROM memory cell, gate layer 156 has a low electron concentration. Consequently, the sense transistor has a relatively low threshold voltage and conducts current with a predetermined voltage applied to control gate terminal 104 during a read operation. Alternatively, when a logical “0” is stored in the EEPROM memory cell, gate layer 156 has a relatively higher electron concentration. The sense transistor has a higher threshold voltage and does not conduct current when the predetermined voltage is applied to control gate terminal 104 during a read operation. By convention, a logical “1” data state is often referred to as erased while a logical “0” state is referred to as programmed.

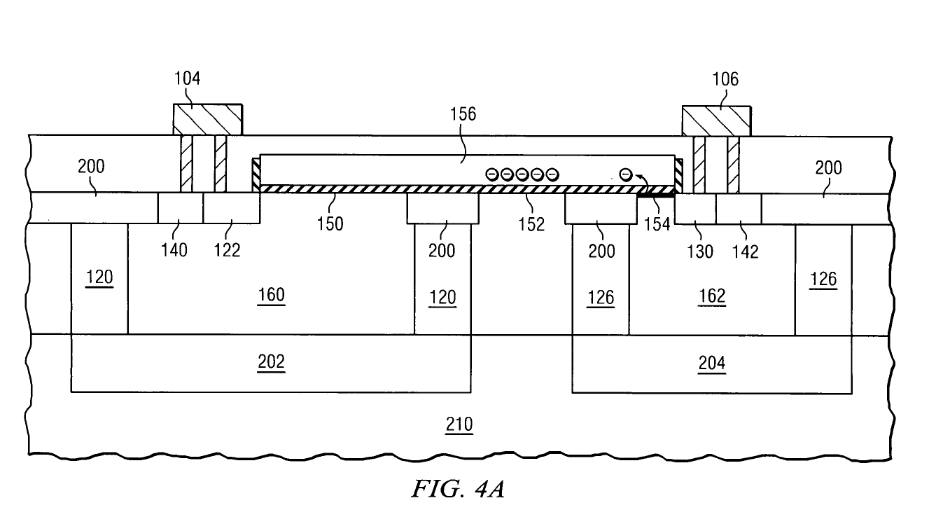

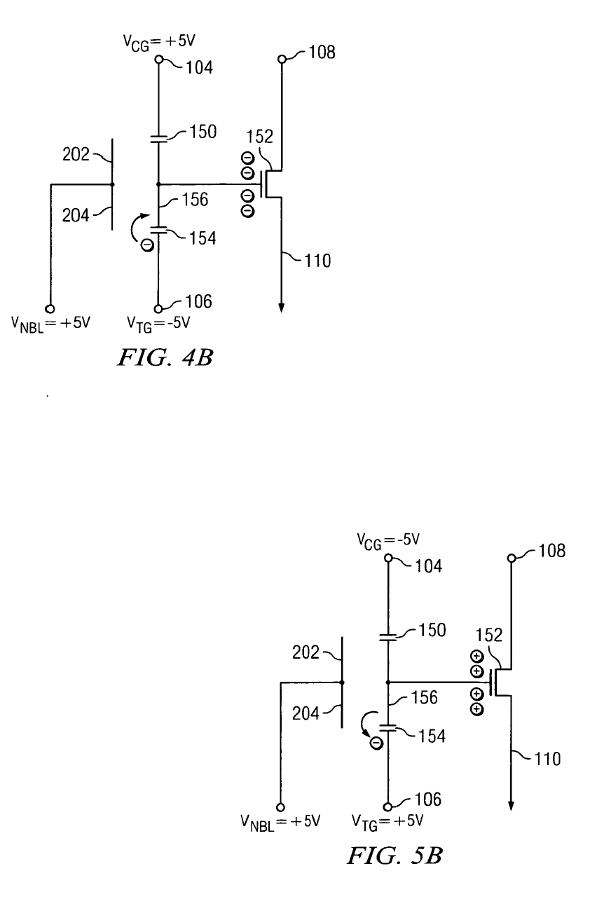

Referring now to FIGS. 4A and 4B, a programming operation of the control gate layer of the memory cell will be explained in detail. Numeric values in the following discussion are given by way of example and may vary with different manufacturing processes. FIG. 4A is a cross sectional view of the memory cell as previously discussed with reference to FIG. 2. FIG. 4B is a schematic diagram of the memory cell of FIG. 4A. N− isolation regions 120 and 126 as well as N+ buried layers 202 and 204 are biased at 5 V throughout the operation. A 5 V signal is applied to control gate terminal 104. P+ region 140 is electrically connected to P− well region 160. Thus, P− well region 160 is also at 5 V. The capacitance of control gate capacitor 150 (C_{CG}) is much larger than the total capacitance (C_{T}) of tunnel gate capacitor 154, sense transistor gate 152, and associated parasitic capacitance. The coupling ratio C_{CG}/(C_{CG}+C_{T}) is at least 0.8 and preferably 0.9 or greater. The polycrystalline silicon gate layer voltage, therefore, is approximately 4 V to 4.5 V.

A −5 V signal is also applied to the tunnel gate terminal 106. P+ region 142 is electrically connected to P− well region 162 which is, therefore, also at −5 V. An inversion layer indicated by the dark region is formed adjacent a second part of polycrystalline silicon gate layer 156 at the tunnel gate capacitor 154 below the intervening dielectric region. This dielectric region is preferably silicon dioxide or other suitable dielectric material as is known in the art. N+ region 130 provides a source of electrons for the inversion layer and remains in conductive contact with the inversion layer. Thus, a high electric field is generated across the relatively thin dielectric region sufficient to induce Fowler-Nordheim tunneling of electrons from the inversion layer to the polycrystalline silicon gate layer 156. This relatively higher concentration of electrons significantly increases the threshold voltage of sense transistor 152 and renders it nonconductive in a subsequent read operation.

The present invention offers several advantages over memory cells of the prior art. First, the critical electric field necessary for Fowler-Nordheim tunneling is developed by positive and negative voltages of comparable magnitudes. This avoids the need to generate a high voltage power supply or to incorporate special high voltage transistors in the manufacturing process. Second, programming by Fowler-Nordheim tunneling greatly reduces the power requirement compared to prior art hot carrier generation methods such as avalanche multiplication and band-to-band tunneling. Third, Fowler-Nordheim tunneling from the inversion layer to the polycrystalline silicon gate layer 156 provides uniform current density over the entire area of the tunnel gate capacitor 154. Thus, current density is much less than with methods of the prior art where current flow was through a much smaller area. Such areas were edge-dependent and determined by overlapping gate and underlying implant regions. The reduced programming current density of the present invention greatly increases program/erase cycles and corresponding reliability of the memory cell.

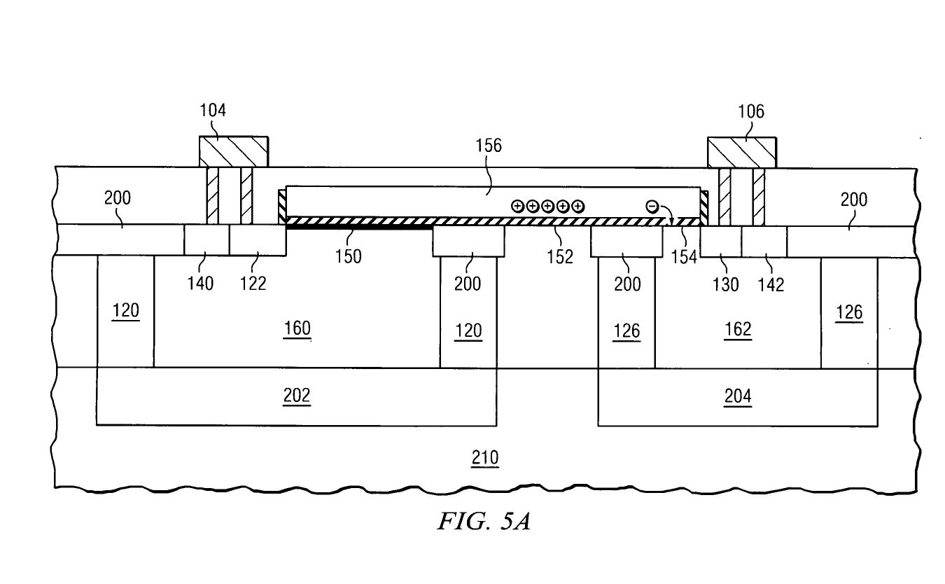

Referring now to FIGS. 5A and 5B, an erase operation of the control gate layer of the memory cell will be explained in detail. FIG. 5A is a cross sectional view of the memory cell as previously discussed with reference to FIG. 2. FIG. 5B is a schematic diagram of the memory cell of FIG. 5A. As previously discussed, N− isolation regions 120 and 126 as well as N+ buried layers 202 and 204 are biased at 5 V throughout the operation. A −5 V signal is applied to control gate terminal 104. P+ region 140 is electrically connected to P− well region 160. Thus, P− well region is also at −5 V. Due to the coupling ratio of control gate capacitor 150 (C_{CG}) and the total capacitance (C_{T}) of tunnel gate capacitor 154, sense transistor gate 152, and associated parasitic capacitance the polycrystalline silicon gate layer voltage is approximately −4 V to −4.5 V. The voltage difference across control gate capacitor 150 forms an inversion layer adjacent a first part of polycrystalline silicon gate layer 156 below the intervening dielectric region as indicated by the dark area. The inversion layer is electrically connected to N+ region 122 and, therefore, maintains the high coupling ratio between C_{CG} and C_{T}.

A 5 V signal is also applied to the tunnel gate terminal 106. P+ region 142 is electrically connected to P− well region 162 which is, therefore, also at 5 V. The voltage difference between the polycrystalline silicon gate 156 and the P− well region 162 forms an accumulation region at the lower plate (P− well region 162) of tunnel gate capacitor 154. The resulting high electric field generated across the relatively thin dielectric region is sufficient to induce Fowler-Nordheim tunneling of electrons from polycrystalline silicon gate layer 156 to the accumulation region. Thus, a relatively lower concentration of electrons significantly decreases the threshold voltage of sense transistor 152 and renders it conductive in a subsequent read operation.

The previously discussed advantages of the present invention are also present during an erase operation. The critical electric field necessary for Fowler-Nordheim tunneling is developed by positive and negative voltages of comparable magnitudes. This avoids the need to generate a high voltage power supply or to incorporate special high voltage transistors in the manufacturing process. Programming by Fowler-Nordheim tunneling greatly reduces the power requirement compared to prior art hot carrier generation methods such as avalanche multiplication and band-to-band tunneling. Finally, Fowler-Nordheim tunneling from the polycrystalline silicon gate layer 156 to the accumulation region provides uniform current density over the entire area of the tunnel gate capacitor 154. Thus, current density is much less than with methods of the prior art where current flow was through a much smaller area. Such areas were edge-dependent and determined by overlapping gate and underlying implant regions. The reduced programming current density of the present invention greatly increases program/erase cycles and corresponding reliability of the memory cell.

Still further, while numerous examples have thus been provided, one skilled in the art should recognize that various modifications, substitutions, or alterations may be made to the described embodiments while still falling with the inventive scope as defined by the following claims. For example, inventive concepts of the present invention are readily adapted to triple well processes where the N− isolation regions and the N+ buried layers are replaced by deep N− well regions. Alternatively, the memory cell of the present invention may be fabricated on an N type substrate. Furthermore, central N-well regions 120 and 126 might be merged into a single central N-well region with a P-channel sense transistor substituted for the N-channel sense transistor 152. Additionally, preferred embodiments of the present invention are directed to a memory cell with a single polycrystalline silicon floating gate. The gate, however, may be formed in segments which are electrically connected in metal. Other combinations will be readily apparent to one of ordinary skill in the art having access to the instant specification.

What is claimed is:

1. A memory cell, comprising:
a sense transistor having a source, a drain, and a control gate layer;
a first lightly doped region having a first conductivity type;
a second lightly doped region having the first conductivity type;
a first dielectric region formed between the control gate layer and the first lightly doped region; and
a second dielectric region formed between the control gate layer and the second lightly doped region.

2. A memory cell as in claim 1, comprising:
a first isolation region formed around the first lightly doped region; and
a second isolation region formed around the second lightly doped region.

3. A memory cell as in claim 2, wherein the first and second isolation regions comprise heavily doped regions having a second conductivity type.

4. A memory cell as in claim 2, wherein the first and second isolation regions comprise lightly doped regions having a second conductivity type.

5. A memory cell as in claim 2, wherein the first and second isolation regions comprise dielectric regions.

6. A memory cell as in claim 2, comprising a third lightly doped region having the first conductivity type formed around the first and second isolation regions.

7. A memory cell as in claim 2, wherein the first isolation region is connected to the second isolation region.

8. A memory cell as in claim 1, comprising:
a first heavily doped region having the first conductivity type formed within the first lightly doped region;
a second heavily doped region having a second conductivity type formed within the first lightly doped region and electrically connected to the first heavily doped region;
a third heavily doped region having the first conductivity type formed within the second lightly doped region; and
a fourth heavily doped region having the second conductivity type formed within the second lightly doped region and electrically connected to the third heavily doped region.

9. A memory cell as in claim 1, wherein the first dielectric region formed between the control gate layer and the first lightly doped region comprises a control gate capacitor; and wherein the second dielectric region formed between the control gate layer and the second lightly doped region comprises a tunnel gate capacitor.

10. A memory cell as in claim 9, wherein a capacitance of the control gate capacitor is at least 10 times greater than a capacitance of the tunnel gate capacitor.

11. A method of programming a gate of a memory cell, comprising:
applying a positive voltage to a control gate terminal of the memory cell with respect to the gate,
applying a negative voltage to a tunnel gate terminal of the memory cell with respect to the gate;
producing an inversion region of the substrate adjacent a first part of the gate; and
conducting electrons from the inversion region to the gate.

12. A method as in claim 11, wherein the first part of the gate is spaced apart from the inversion region by a dielectric region.

13. A method as in claim 12, wherein the dielectric region comprises silicon dioxide.

14. A method as in claim 12, comprising conducting electrons from the inversion region to the gate by Fowler-Nordheim tunneling.

15. A method as in claim 11, comprising producing an accumulation region of the substrate adjacent a second part of the gate.

16. A method as in claim 11, wherein the gate comprises a single polycrystalline silicon layer.

17. A method as in claim 11, wherein the control gate terminal comprises a first heavily doped region having a first conductivity type electrically connected to a second heavily doped region having a second conductivity type, and wherein the tunnel gate terminal comprises a third heavily doped region having the first conductivity type electrically connected to a fourth heavily doped region having the second conductivity type.

18. A method of erasing a gate of a memory cell, comprising:
applying a negative voltage to a control gate terminal of the memory cell with respect to the gate,
applying a positive voltage to a tunnel gate terminal of the memory cell with respect to the gate;
producing an accumulation region of the substrate adjacent a first part of the gate; and
conducting electrons from the gate to the accumulation layer.

19. A method as in claim 18, wherein the accumulation region of the substrate is spaced apart from the first part of the gate by a dielectric region.

20. A method as in claim 19, wherein the dielectric region comprises silicon dioxide.

21. A method as in claim 19, comprising conducting electrons from the gate to the accumulation region by Fowler-Nordheim tunneling.

22. A method as in claim 18, comprising producing an inversion region of a substrate adjacent a second part of the gate.

23. A method as in claim 18, wherein the gate comprises a single polycrystalline silicon layer.

24. A method as in claim 18, wherein the control gate terminal comprises a first heavily doped region having a first conductivity type electrically connected to a second heavily doped region having a second conductivity type, and wherein the tunnel gate terminal comprises a third heavily doped region having the first conductivity type electrically connected to a fourth heavily doped region having the second conductivity type.
